(19) United States
(12) Patent Application Publication
(10) Pub. No.: US 2010/0277158 A1
(43) Pub. Date: Nov. 4, 2010

(54) DELAY TIME MEASUREMENT CIRCUIT AND METHOD

(76) Inventors: Bang-Won Lee, Gyeonggi-do (KR); Duck-Young Jung, Gyeonggi-do (KR); Young-Ho Shin, Gyeonggi-do (KR); Jei-Hyuk Lee, Gyeonggi-do (KR); Ju-Min Lee, Gyeonggi-do (KR)

Correspondence Address: CANTOR COLBURN, LLP, 20 Church Street, 22nd Floor, Hartford, CT, 06103, US

(21) Appl. No.: 12/664,807

(22) PCT Filed: Jun. 17, 2008
(86) PCT No.: PCT/KR2008/003422

§ 371 Date: Jun. 17, 2010

(30) Foreign Application Priority Data
Jun. 18, 2007 (KR) 10-2007-0059389

(51) Int. Cl. G01R 29/00

(52) U.S. Cl. 324/76.79

(57) ABSTRACT

Provided are a delay time measurement circuit and method. Since the delay time measurement circuit and method according to the present invention use a delay chain having a feedback structure, a measurable delay time is not limited. In addition, the number of delay elements constituting the delay chain can be reduced, such that the delay time measurement circuit can be implemented in a small layout area.

### TECHNICAL FIELD

The present invention relates to a delay time measurement circuit and method, and more particularly, to a delay time measurement circuit including a delay chain having a feedback structure and a delay time measurement method.

### BACKGROUND ART

Delay time measurement circuits measure a time interval from a reference time to a time at which a measured signal is applied, and output a value corresponding to the measured time interval. A delay time measurement circuit outputting digital data as the measured time interval is also referred to as a time-to-digital converter circuit, and is employed in various electronic devices. In general, the delay time measurement circuit capable of outputting a time-domain value using digital data receives a reference signal for specifying a measurement start time and a measurement signal to be measured and measures a delay time of the measurement signal with respect to the reference signal. Here, the delay time measurement circuit can measure the delay time using a variety of methods. According to a typical method, the delay time measurement circuit has a delay chain to measure a delay time.

FIG. 1 is a circuit diagram of an example of a conventional delay time measurement circuit that measures a delay time using a delay chain.

FIG. 1 is disclosed in Korean Patent Application No. 2005-117183 (referred to as a cited invention), showing a sensor or Analog-to-Digital Converter (ADC) converting a change in impedance or voltage into a delay difference and measuring the delay difference. In FIG. 1, the delay time measurement circuit 1 comprises a read signal generator 10, a reset signal generator 20, a delay chain 30, a thermometer code generator 40 and a binary code decoder 50.

The read signal generator 10 comprises an inverter I1 for inverting and delaying a reference signal ref, inverters I2 and I3 for delaying a measurement signal sen, and an AND gate AND1 for performing an AND operation on the inverted and delayed reference signal ref and the delayed measurement signal sen to generate a read signal clocked in synchronization with a rising edge of the inverted and delayed reference signal ref. The reset signal generator 20 comprises inverters I4 and I5 for delaying the measurement signal sen, an XOR gate XOR for performing an XOR operation on the delayed measurement signal sen and the non-delayed measurement signal sen to generate a signal clocked in synchronization with rising and falling edges of the measurement signal sen, and an AND gate AND2 for performing the AND operation on the output signal of the XOR gate XOR and the delayed measurement signal sen to generate a reset signal clocked in synchronization with a falling edge of the delayed measurement signal sen.

Here, while the read signal read is generated through the even number of inverters I2 and I3 and the AND gate AND1, the reset signal reset is generated through the even number of inverters I4 and I5, the XOR gate XOR and the AND gate AND2. Thus, the read signal read is clocked before the reset signal reset. In other words, since the reset signal reset is generated through the one more logical gate XOR in comparison with the read signal read, the read signal read is clocked before the reset signal reset.

The delay chain 30 comprises a plurality of delay elements D1 to D7 connected in series, delaying the reference signal ref to generate a plurality of delay signals delay1 to delay7. The thermometer code generator 40 comprises a plurality of D flip-flops D-FF1 to D-FF7 latching the measurement signal sen in response to the delay signals delay1 to delay7 to generate a plurality of output signals Q1 to Q7 and reset by the reset signal, and a plurality of NAND gates NAND1 to NAND7 for performing the NAND operation on the plurality of output signals Q1 to Q7 of the plurality of D flip-flops D-FF1 to D-FF7 and the read signal read to generate a thermometer code. And the binary code decoder 50 converts the thermometer code into a binary code b_code.

Operation of the delay time measurement circuit 1 of FIG. 1 will be described with reference to FIG. 2.

When receiving the reference signal ref and the measurement signal sen having the same delay time, the delay time measurement circuit 1 operates as follows.

The delay chain 30 delays the reference signal ref through the delay elements D1 to D7 to generate the delay signals delay1 to delay7 having different delay times, and all D flip-flops D-FF1 to D-FF7 latch the measurement signal sen having high level in synchronization with rising edges of the respective delay signals delay1 to delay7 to generate the output signals Q1 to Q7 having high level.

When the read signal read is clocked after a specific time, the NAND gates NAND1 to NAND7 perform the NAND operation on the read signal and the output signals Q1 to Q7 to generate a thermometer code having a value of “0” (0000000). Then, the binary code decoder 50 receives the thermometer code, converts the received thermometer code into a binary code b_code, and outputs the binary code b_code.

However, when the reference signal ref and the measurement signal sen having a delay difference tdiff are applied to the delay time measurement circuit 1, the D flip-flop D-FF1 receives the delay signal delay1 having a shorter delay time than the measurement signal sen, and the other D flip-flops D-FF2 to D-FF7 receive the delay signals delay2 to delay7 having a longer delay time than the measurement signal sen.

Then, the D flip-flop D-FF1 latches the measurement signal sen having low level to generate the output signal Q1 having low level, and the other D flip-flops D-FF2 to D-FF7 latch the measurement signal sen having high level to generate the output signals Q2 to Q7 having high level, like the former case.

When the read signal read is clocked after a specific time, the NAND gates NAND1 to NAND7 generate a thermometer code “1000000” in response to the output signals Q1 to Q7 of the D flip-flops D-FF1 to D-FF7. In other words, the thermometer code has a value corresponding to the delay difference tdiff between the reference signal ref and the measurement signal sen.

The binary code decoder 50 receives the thermometer code having the value corresponding to the delay difference tdiff, converts the thermometer code into the binary code b_code, and outputs the binary code b_code.

In this way, the delay time measurement circuit 1 lets the D flip-flops D-FF1 to D-FF7 output the output signals Q1 to Q7 having different levels according to the delay difference between the reference signal ref and the measurement signal sen, thereby calculating the delay difference between the reference signal ref and the measurement signal sen.

In the delay time measurement circuit 1 shown in FIG. 1, the length and precision of a measurable total delay time are determined by the delay elements D1 to D7 constituting the delay chain 30. More specifically, a delay time for which the respective delay elements D1 to D7 delay the reference signal ref determines the precision of the delay time that can be measured by the delay time measurement circuit 1, and the number of the delay elements D1 to D7 determines the length of the measurable delay time.

For example, when the delay chain 30 includes fifty delay elements each having a delay time of 10 ns, the measurable total delay time is 500 ns (50*10 ns), which may be calculated by “the number of delay elements*the delay time of delay elements”. Here, the precision of the measurable delay time is the delay time of each delay element, that is, 10 ns. In other words, the unit of measurable delay time is 10 ns.

When the delay chain 30 includes twenty delay elements each having a delay time of 10 ns, the precision of measurable delay time is 10 ns. Since the number of delay elements is twenty, the measurable total delay time is 200 ns (20*10 ns).

When the delay chain 30 includes fifty delay elements each having a delay time of 5 ns, the precision of measurable delay time is 5 ns, and the measurable total delay time is 250 ns (50*5 ns).

In brief, when the delay time of delay elements is reduced, the measurable total delay time is reduced even if the delay chain 30 includes the same number of delay elements. In other words, even if the total delay time to be measured is fixed, a larger number of delay elements are needed in the delay chain 30 to increase measurement precision.

As a result, the delay time measurement circuit 1 having the delay chain 30 needs a larger number of delay elements to measure a longer delay time and increase precision.

### DISCLOSURE

### Technical Problem

The present invention is directed to providing a delay time measurement circuit that includes a plurality of delay elements constituting a delay chain in a feedback structure and thus can measure a long delay time using a small number of delay elements, and a delay time measurement method of the delay time measurement circuit.

### Technical Solution

One aspect of the present invention provides a delay time measurement circuit comprising: a delay chain unit that selects either a reference signal indicating a start of delay time measurement or a feedback signal to receive the selected signal as an input signal, has a plurality of delay elements connected in series to delay the input signal, inverts the delayed input signal, outputs the inverted signal as the feedback signal, and counts a number of feedback iterations of the inverted signal to output an iterative count signal; a code generation unit for comparing a measurement signal with the input signal and each of a plurality of delay signals applied from the delay elements except a last delay element to measure a delay time of the measurement signal with respect to the reference signal to generate code signals; and a decoder for decoding the code signals and the iterative count signal to output a measured delay value.

The delay chain unit may comprise: a switch for selecting the reference signal or the feedback signal and outputting the selected signal as the input signal; a delay chain having the delay elements connected in series and receiving and delaying the input signal to output the delay signals; an inverter for inverting a delay signal output from the last delay element of the delay chain to output the feedback signal; and a counter for outputting the iterative count signal in response to the feedback signal.

The switch selects either the reference signal or the feedback signal in response to the iterative count signal and outputs the input signal.

The code generation unit may comprise: a comparative delay signal generator for generating the input signal and the delay signals as a plurality of comparative delay signals when the iterative count signal is an even number, and inverting the input signal and the delay signals to output the inverted signals as the comparative delay signals when the iterative count signal is an odd number; a plurality of comparators for comparing the respective comparative delay signals with the measurement signal to generate the code signals; and a first logical gate for outputting a counter reset signal for controlling the counter in response to the code signals.

The counter may be reset in response to the counter reset signal.

The comparative delay signal generator may comprise a plurality of exclusive logical sum (XOR) gates for performing an XOR operation on one lowermost bit of the iterative count signal and each of the input signal and the comparative delay signals.

The comparators may be a plurality of first logical multiplication (AND) gates for performing an AND operation on the respective comparative delay signals and the measurement signal.

The comparators may be D flip-flops latching and outputting the measurement signal in response to the comparative delay signals and reset in response to the switch setting signal.

The first logical gate may be a logical sum (OR) gate for performing an OR operation on the code signals.

The decoder may multiply a number of the delay elements by the iterative count signal and add a value corresponding to the code signals to the multiplied result to output the measured delay value.

The code generation unit may comprise an edge detector outputting a reset signal for resetting the counter in response to an edge of the reference signal, outputting a count stop signal to the counter in response to an edge of the measurement signal, outputting the code signals corresponding to a number of edges of the delay signals.

The counter may output the iterative count signal to the decoder in response to the count stop signal and be reset in response to the reset signal.

The counter may output the iterative count signal to the decoder and be reset in response to the count stop signal.

The decoder may multiply a number of the delay elements by the iterative count signal and add a value obtained by decoding the code signals to the multiplied result to output the measured delay value.

The switch may be a second AND gate for performing an AND operation on the reference signal, the feedback signal and the count stop signal to output the input signal.

Another aspect of the present invention provides a delay time measurement circuit comprising: a delay chain unit selecting either a reference signal indicating a start of delay time measurement or a feedback signal to receive the selected signal as an input signal, having a plurality of delay elements connected in series to delay the input signal, inverting the delayed input signal, and outputting the inverted signal as the feedback signal; and an edge counter for counting edges of the input signal and delay signals applied from the delay elements in response to an edge of the reference signal, and outputting a measured delay value corresponding to a number of the counted edges of the input signal and the delay signals in response to an edge of a measurement signal.

The delay chain unit may comprise: a switch for selecting the reference signal or the feedback signal to output the selected signal as the input signal; a delay chain having the delay elements connected in series and receiving and delaying the input signal to output the delay signals; and an inverter for inverting a delay signal output from a last delay element of the delay chain to output the feedback signal.

Still another aspect of the present invention provides a delay time measurement method comprising: generating a plurality of delay signals in response to either a reference signal or a feedback signal, and determining whether or not a measurement signal is ascertained; when the measurement signal is not ascertained, inverting a last delay signal among the delay signals to output the feedback signal, and feeding back the feedback signal to the step of generating the delay signals; and when the measurement signal is ascertained, counting edges of delay signals generated until the measurement signal is applied, and generating a measured delay value using a number of the counted edges of the delay signals and a number of operations of outputting the feedback signal.

Generating the delay signals and determining whether or not the measurement signal is applied may comprise: when the reference signal is applied, resetting a number of operations of generating the feedback signal; delaying the reference signal or the feedback signal for different times to output the delay signals; counting edges of the delay signals; and determining whether or not the measurement signal is ascertained.

Feeding back the feedback signal may comprise: when the measurement signal is not ascertained, inverting the last delay signal among the delay signals to generate the feedback signal; in response to the feedback signal, increasing a value of an iterative count signal and outputting the iterative count signal; resetting the number of the counted edges of the delay signals in response to the iterative count signal; and feeding back the feedback signal to the step of generating the delay signals.

Generating the measured delay value may comprise: when the measurement signal is ascertained, generating code signals in response to the number of the edges of the delay signals generated until the measurement signal is ascertained; and decoding the iterative count signal and the code signals to output the measured delay value.

### ADVANTAGEOUS EFFECTS

A delay time measurement circuit and method according to the present invention use a delay chain having a feedback structure, and thus a measurable delay time is not limited. Therefore, even if the delay times of respective delay elements are set to be short, long total delay times can be accurately measured. In addition, the number of delay elements constituting a delay chain can be reduced, such that the delay time measurement circuit can be implemented in a small layout area.

### DESCRIPTION OF DRAWINGS

FIG. 1 is a circuit diagram of an example of a conventional delay time measurement circuit that measures a delay time using a delay chain;

FIG. 2 is a timing diagram illustrating operation of the delay time measurement circuit of FIG. 1;

FIG. 3 is a circuit diagram of another example of a delay time measurement circuit using a delay chain;

FIG. 4 is a circuit diagram of a delay time measurement circuit including a delay chain having a feedback structure according to an exemplary embodiment of the present invention;

FIG. 5 is a timing diagram illustrating operation of the delay time measurement circuit of FIG. 4;

FIG. 6 is a circuit diagram of a delay time measurement circuit including a delay chain having a feedback structure according to another exemplary embodiment of the present invention;

FIG. 7 is a flowchart showing a delay time measurement method of the delay time measurement circuit of FIG. 6; and

FIG. 8 is a circuit diagram of a delay time measurement circuit including a delay chain having a feedback structure according to still another exemplary embodiment of the present invention.

### MODES OF THE INVENTION

Hereinafter, exemplary embodiments of the present invention will be described in detail. However, the present invention is not limited to the exemplary embodiments disclosed below, but can be implemented in various forms. The following exemplary embodiments are described in order to enable those of ordinary skill in the art to embody and practice the invention.

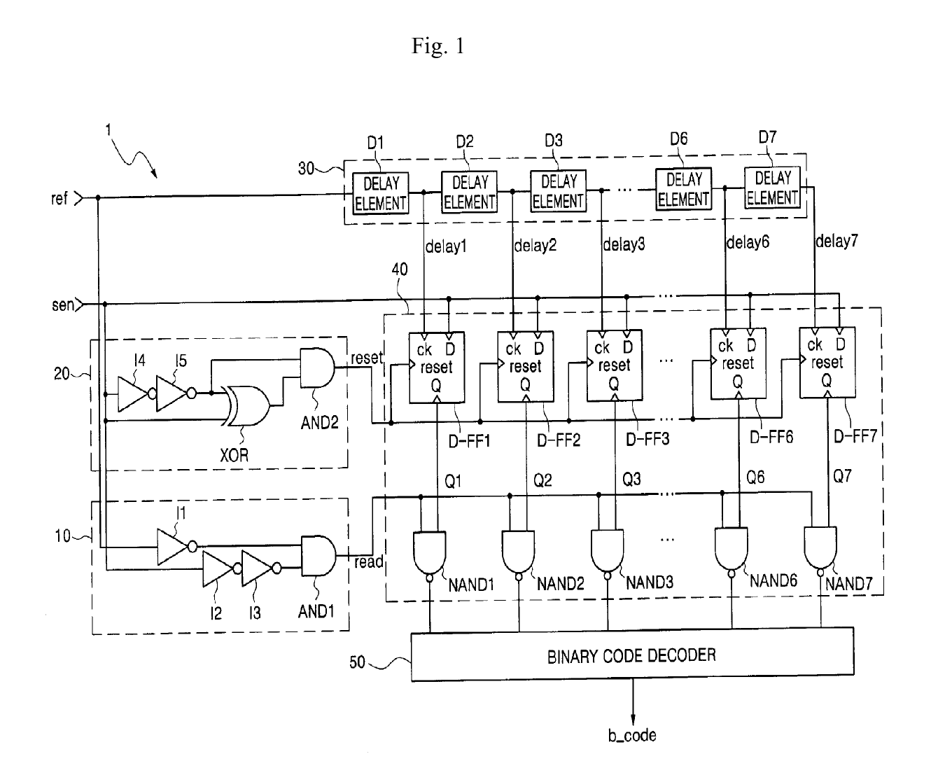

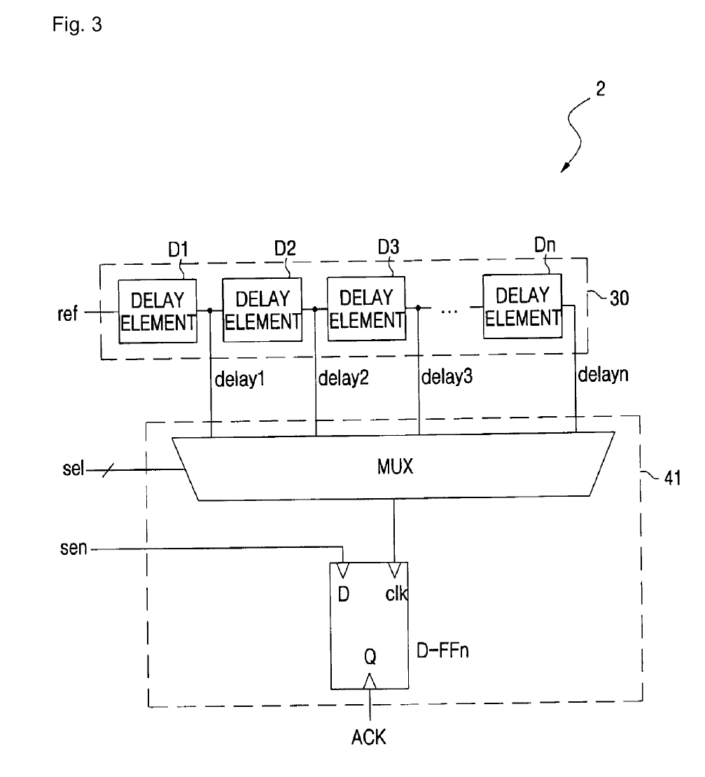

FIG. 3 is a circuit diagram of another example of a delay time measurement circuit using a delay chain. The delay time measurement circuit 1 shown in FIG. 1 is constituted to generate a thermometer code as a measured delay time, and has the read signal generator 10 and the reset signal generator 20 for generating a read signal read and a reset signal reset for controlling the thermometer code generator 40. The thermometer code generator 40 has the D flip-flops D-FF1 to D-FF7 and the NAND gates NAND1 to NAND7 numbering the same as the delay elements D1 to D7 constituting the delay chain 30. The delay time measurement circuit 1 of FIG. 1 is constituted to generate a thermometer code in parallel such that the binary decoder 50 generates a binary code b_code. It is also natural that the thermometer code is serially or parallelly transferred to a next logic without generating the binary code b_code.

In a delay time measurement circuit 2 of FIG. 3, a thermometer code generator 41 has one multiplexer MUX and one D flip-flop D-FFn. The multiplexer MUX receives delay signals delay1 to delayn from a plurality of delay elements D1 to Dn of a delay chain 30, and selects and outputs the delay signals delay1 to delayn in sequence in response to a selection signal sel. The delay signals delay1 to delayn applied from the delay chain 30 are delayed by the respective delay elements D1 to Dn and applied to the multiplexer MUX in sequence, and the multiplexer MUX selects and outputs one of the delay signals delay1 to delayn. The D flip-flop D-FFn receives the output signal of the multiplexer MUX as a clock signal clk, latches a measurement signal sen in response to the clock signal clk, and outputs an output signal ACK. The selection signal sel is changed for selecting and outputting another of the delay signals delay1 to delayn in response to the output signal ACK. The selection signal sel is determined by a conventional Successive Approximation Register (SAR) scheme or a sequential +1/−1 code conversion scheme. Since these schemes are well known in the art, detailed descriptions thereof will be omitted. Therefore, the delay time measurement circuit 2 shown in FIG. 3 outputs a thermometer code in sequence and does not need the read signal generator 10 and the reset signal generator 20 of FIG. 1. In the result, the delay time measurement circuit 2 of FIG. 3 has a very simple constitution in comparison with the delay time measurement circuit 1 of FIG. 1.

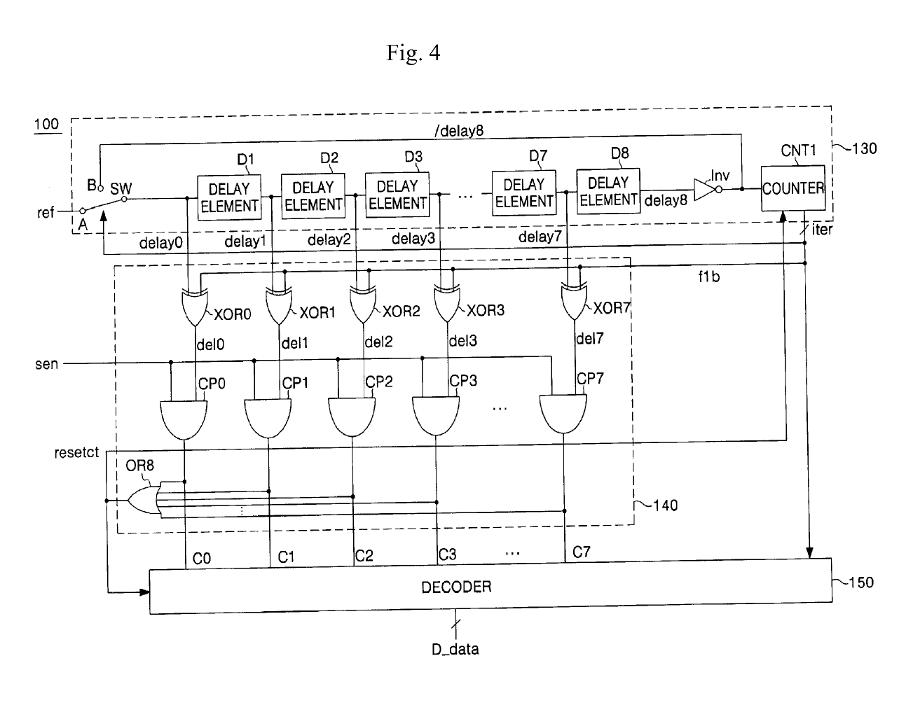

FIG. 4 is a circuit diagram of a delay time measurement circuit including a delay chain having a feedback structure according to an exemplary embodiment of the present invention.

The delay time measurement circuit 100 of FIG. 4 has a delay chain 130 having a feedback structure, a code generation unit 140 and a decoder 150.

The delay chain 130 has a plurality of delay elements D1 to D8, a switch SW, an inverter Inv and a counter CNT1. The delay elements D1 to D8 are connected in series, and a delay signal delay8 output from the last delay element D8 among the delay elements D1 to D8 connected in series is inverted by the inverter Inv and applied to the switch SW. When a reference signal ref is applied to the delay chain 130 having a feedback structure without an inverter and fed back to the delay elements D1 to D8, delay signals delay0 to delay8 have the same state at all times and thus cannot be compared with a measurement signal sen. Therefore, the inverter Inv is prepared for inverting the delay signal delay8 to change the state of the delay signal delay8 every time that the delay signal delay8 is fed back. The switch SW selects the reference signal ref in an initial state, that is, when an iterative count signal iter of the counter CNT1 is “0”, selects an inverted delay signal /delay8 when the iterative count signal iter is not “0”, and applies the selected signal as the delay signal delay0 to the first delay element D1. In other words, the delay chain 130 of FIG. 4 has a feedback structure, unlike the delay chain 30 of FIG. 1. In response to the inverted delay signal /delay8, the counter CNT1 counts the number of operations of delaying the reference signal ref in the delay chain 130 and outputs the iterative count signal iter. The counter CNT1 is reset in response to a counter reset signal resetct. It is natural that any logic circuit, such as odd number of inverter stages for delay element D8 and even number of inverter stages for delay element D1 to D7, that makes inverted polarity per every iteration can be used.

The code generation unit 140 has a plurality of XOR gates XOR0 to XOR7, a plurality of AND gates CP0 to CP7 and an OR gate OR8. Among the XOR gates XOR0 to XOR7, the XOR gate XOR0 performs an XOR operation on the reference signal ref applied from the switch SW or the inverted delay signal /delay8 applied from the inverter Inv as the delay signal delay0 and one bit flb of the iterative count signal iter output from the counter CNT1, thereby outputting a comparative delay signal del0. The other XOR gates XOR1 to XOR7 receive the delay signals delay1 to delay7 output from the delay elements D1 to D7 and the one bit flb of the iterative count signal iter output from the counter CNT1 and perform the XOR operation on them, thereby outputting comparative delay signals del1 to del7. Here, the one bit flb of the iterative count signal iter is used to determine whether the iterative count signal iter is an odd number or an even number, and may be the last bit of the iterative count signal iter. Since the inverter Inv applies the inverted delay signal /delay8 to the switch SW in the delay chain 130, the delay signals delay0 to delay7 repeated an odd number of times have the opposite phase to the reference signal ref when the iterative count signal iter has an initial value of 0. Therefore, the XOR gates XOR0 to XOR7 determine whether the iterative count signal iter is an odd number or an even number using the last bit flb of the iterative count signal iter. The XOR gates XOR0 to XOR7 intactly output the delay signals delay0 to delay7 as the comparative delay signals del0 to del7 when the iterative count signal iter is an even number, and invert the delay signals delay0 to delay7 to output the inverted delay signals /delay0 to /delay7 as the comparative delay signals del0 to del7 when the iterative count signal iter is an odd number. The AND gates CP0 to CP7 perform an AND operation on the measurement signal sen and the respective comparative delay signals del0 to del7, thereby outputting a plurality of code signals C0 to C7. The OR gate OR8 performs an OR operation on the code signals C0 to C7, thereby outputting the counter reset signal resetct. When one of the code signals C0 to C7 becomes high level, the counter reset signal resetct is set up, and the code signals C0 to C7 and the iterative count signal iter are stored in the decoder 150. The decoder 150 decodes the stored code signals C0 to C7 and the iterative count signal iter, thereby outputting a measured delay value D_data. Here, the measured delay value D_data is output in the form set by a user. FIG. 4 illustrates that the OR gate OR8 is used to output the counter reset signal resetct, but another logical gate may be used according to the level of the code signals C0 to C7 responding to the measurement signal sen. The AND gates CP0 to CP7 may be implemented by D flip-flops as illustrated in FIG. 1.

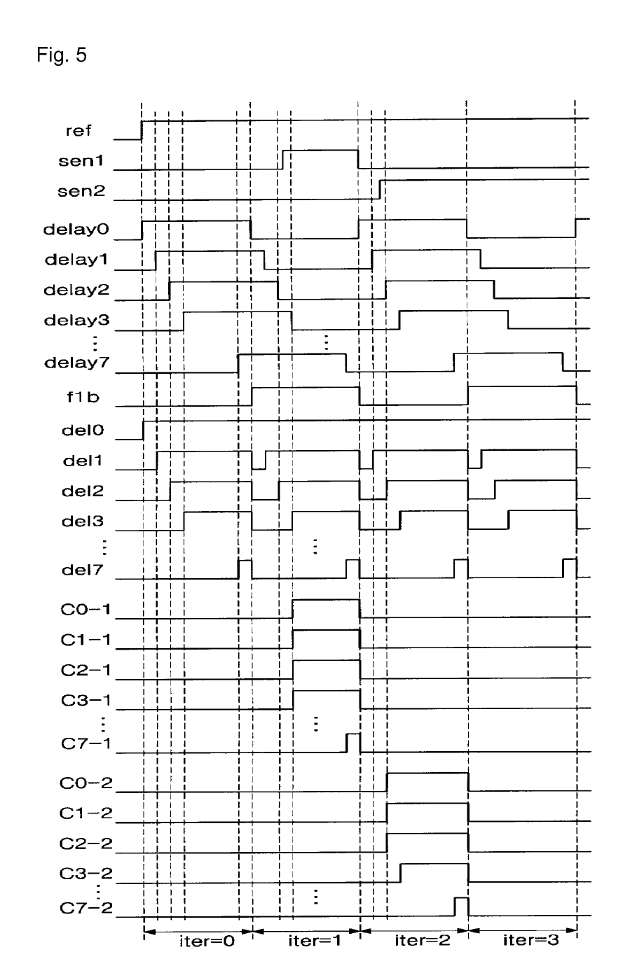

FIG. 5 is a timing diagram illustrating operation of the delay time measurement circuit of FIG. 4.

In FIG. 5, the measurement signal sen is classified into a first measurement signal sen1 and a second measurement signal sen2 to describe two cases.

Operation of the delay time measurement circuit 100 of FIG. 4 will be described with reference to FIG. 5. When a reference signal ref is applied, the switch SW applies the reference signal ref as a delay signal delay0 to the delay elements D1 to D7. The reference signal ref is output as the delay signal delay0 and the first delay element D1 receives and delays the delay signal delay0 to output a delay signal delay1. The other delay elements D2 to D8 each receive and delay delay signals delay1 to delay7 output from the previous delay elements D1 to D7, thereby outputting delay signals delay2 to delay8.

The XOR gates XOR0 to XOR7 perform the XOR operation on a last one bit flb of an iterative count signal iter output from the counter CNT1 and the respective delay signals delay0 to delay7, thereby outputting comparative delay signals del0 to del7. Assuming that the iterative count signal iter is output in the form of binary code, an initial value is “0000”, and thus the last bit flb is “0”. Therefore, the delay signals delay0 to delay7 are output as the comparative delay signals del0 to del7.

The AND gates CP0 to CP7 receive the first measurement signal sen1 and the comparative delay signals del0 to del7, and output code signals C0-1 to C7-1 having high level when the first measurement signal sen1 and the comparative delay signals del0 to del7 all are high level. In FIG. 5, however, the first measurement signal sen1 is kept at low level, and thus all code signals C0-1 to C7-1 are output at low level. Since all code signals C0-1 to C7-1 have low level, the OR gate OR8 outputs the counter reset signal resetct at low level.

The counter reset signal resetct has low level, and thus the decoder 150 does not decode the code signals C0-1 to C7-1.

In response to the counter reset signal resetct having low level, the counter CNT1 detects and counts rising or falling edges of the delay signal delay8, thereby outputting the iterative count signal iter of “0001”.

Since the iterative count signal iter is not “0000”, the switch SW outputs an inverted delay signal /delay8 as the delay signal delay0, and the first delay element D1 receives and delays the delay signal delay0 to output the delay signal delay1. The other delay elements D2 to D8 receive and delay the delay signals delay1 to delay7 output from the respective previous delay elements D1 to D7, thereby outputting the delay signals delay2 to delay8.

The iterative count signal iter output from the counter CNT1 is “0001”, and thus the last bit flb is “1”. Therefore, the XOR gates XOR0 to XOR7 invert the delay signals delay0 to delay7 to output the inverted delay signals as the comparative delay signals del0 to del7.

Since the first measurement signal sen1 is at high level when the comparative delay signal del3 is at high level, the AND gates CP0 to CP7 output the code signals C0-1 to C3-1 at high level and the code signals C4-1 to C7-1 at low level. The OR gate OR8 outputs the counter reset signal resetct at high level in response to the code signals C0-1 to C3-1 having high level. The counter CNT1 is reset in response to the counter reset signal resetct having high level.

When the counter reset signal resetct having high level is applied, the decoder 150 decodes the iterative count signal iter applied from the counter CNT1 and the code signals C0-1 to C7-1 to output a measured delay value D_data.

TABLE 1

| C0 | C1 | C2 | C3 | C4 | C5 | C6 | C7 | Measured code value |
|---|---|---|---|---|---|---|---|---|
| 1 | 0 | 0 | 0 | 0 | 0 | 0 | 0 | 0 |
| 1 | 1 | 0 | 0 | 0 | 0 | 0 | 0 | 1 |
| 1 | 1 | 1 | 0 | 0 | 0 | 0 | 0 | 2 |
| 1 | 1 | 1 | 1 | 0 | 0 | 0 | 0 | 3 |
| 1 | 1 | 1 | 1 | 1 | 0 | 0 | 0 | 4 |
| 1 | 1 | 1 | 1 | 1 | 1 | 0 | 0 | 5 |
| 1 | 1 | 1 | 1 | 1 | 1 | 1 | 0 | 6 |
| 1 | 1 | 1 | 1 | 1 | 1 | 1 | 1 | 7 |

Table 1 shows measured code values corresponding to parts of the measured delay value D_data generated from the decoder 150 in response to the code signals C0-1 to C7-1. The measured delay value D_data is calculated by “the iterative count signal iter*the number of delay elements D1 to D8+a measured code value”. In FIG. 5, a measured code value generated in response to the first measurement signal sent is 3. Therefore, a value of 11 (1*8+3) is output as the measured delay value D_data with respect to the first measurement signal sent. The delay time of the first measurement signal sen1 with respect to the reference signal ref equals “the measured delay value D_data*the delay time of a delay element”. Consequently, when the delay time of the delay elements D1 to D8 is 10 ns, the delay time of the first measurement signal sen1 is 110 ns.

When the second measurement signal sen2 is applied to the delay time measurement circuit 100, a process performed until a feedback operation is first performed is the same as that of the first measurement signal sen1. When the inverted delay signal /delay8 is applied to the switch SW as a first feedback, it is output as the delay signal delay0. Then, the first delay element D1 receives and delays the delay signal delay0, thereby outputting the delay signal delay1. The other delay elements D2 to D8 each receive and delay the delay signals delay1 to delay7 output from the previous delay elements D1 to D7, thereby outputting the delay signals delay2 to delay8.

The iterative count signal iter output from the counter CNT1 is “0001”, and the last bit flb is “1”. Therefore, the XOR gates XOR0 to XOR7 invert the delay signals delay0 to delay7 to output the inverted delay signals as the comparative delay signals del0 to del7.

The second measurement signal sen2 is kept at low level, and thus the AND gates CP0 to CP7 output all code signals C0-2 to C7-2 at low level. Since all code signals C0-2 to C7-2 are at low level, the OR gate OR8 outputs the counter reset signal resetct at low level.

Since the counter reset signal resetct is at low level, the decoder 150 does not decode the code signals C0-2 to C7-2.

In response to the counter reset signal resetct having low level, the counter CNT1 detects and counts rising or falling edges of the delay signal delay8, thereby outputting the iterative count signal iter of “0010”.

Since the switch SW is connected with the inverter Inv, the inverted delay signal /delay8 is output as the delay signal delay0, and the first delay element D1 receives and delays the delay signal delay0 to output the delay signal delay1. The other delay elements D2 to D8 receive and delay the delay signals delay1 to delay7 output from the respective previous delay elements D1 to D7, thereby outputting the delay signals delay2 to delay8.

The iterative count signal iter output from the counter CNT1 is “0010”, and thus the last bit flb is “0”. Therefore, the XOR gates XOR0 to XOR7 output the delay signals delay0 to delay7 as the comparative delay signals del0 to del7.

Since the second measurement signal sen2 is at high level when the comparative delay signal del2 is applied at high level, the AND gates CP0 to CP7 output the code signals C0-2 to C2-2 at high level and the code signals C3-2 to C7-2 at low level. Subsequently, when the comparative delay signals del3 to del7 are applied at high level, the second measurement signal sen2 is at high level. Thus, the code signals C3-2 to C7-2 are also output at high level in sequence. The OR gate OR8 outputs the counter reset signal resetct at high level in response to the code signals C0-2 to C2-2 having high level, and the counter CNT1 is reset in response to the counter reset signal resetct having high level.

When the counter reset signal resetct having high level is applied, the decoder 150 decodes the iterative count signal iter applied from the counter CNT1 and the code signals C0-2 to C7-2 to output the measured delay value D_data. A value of 18 (2*8+2) is output as the measured delay value D_data with respect to the second measurement signal sen2. Consequently, when the delay time of the delay elements D1 to D8 is 10 ns, the delay time of the second measurement signal sen2 is 180 ns.

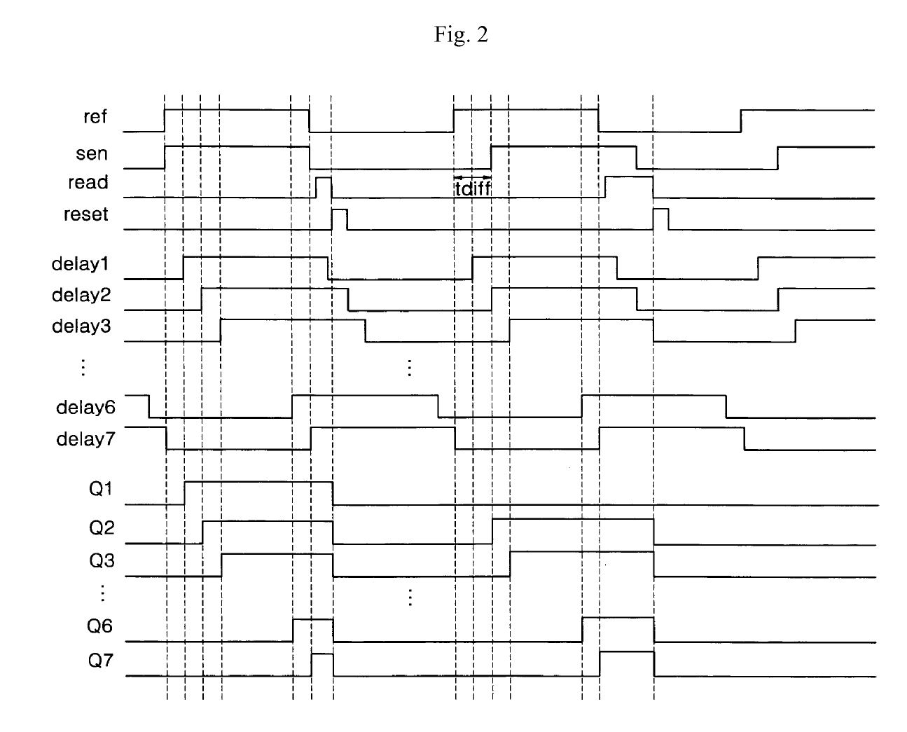

A delay time that can be measured by the delay time measurement circuit 1 shown in FIG. 1 is limited by the number of delay elements, as illustrated in FIG. 2. On the other hand, the delay time measurement circuit 100 shown in FIG. 4 has the delay chain 130 having a feedback structure, and thus a delay time that can be measured by the delay time measurement circuit 100 is not limited. Therefore, even though the delay time of respective delay elements is set to be short, a long total delay time can be measured with accuracy. Theoretically, it is possible to measure any length of delay time using only two delay elements. However, a little delay time is substantially caused by the inverter Inv or the length of a line in the delay chain 130, and may cause an error in a measured delay time when the number of feedbacks increases. One example to minimize the inverter Inv delay is to make delay time difference between delay elements D1 to D7 and delay element D8 by one inverter delay. If the delay element is composed of multiple of inverter logic Inv, then compensating delay time of the inverter Inv becomes easy. Therefore, it is preferable to adjust the number of delay elements included in the delay chain 130 upon design of the delay time measurement circuit 100 in consideration of an expected maximum delay time.

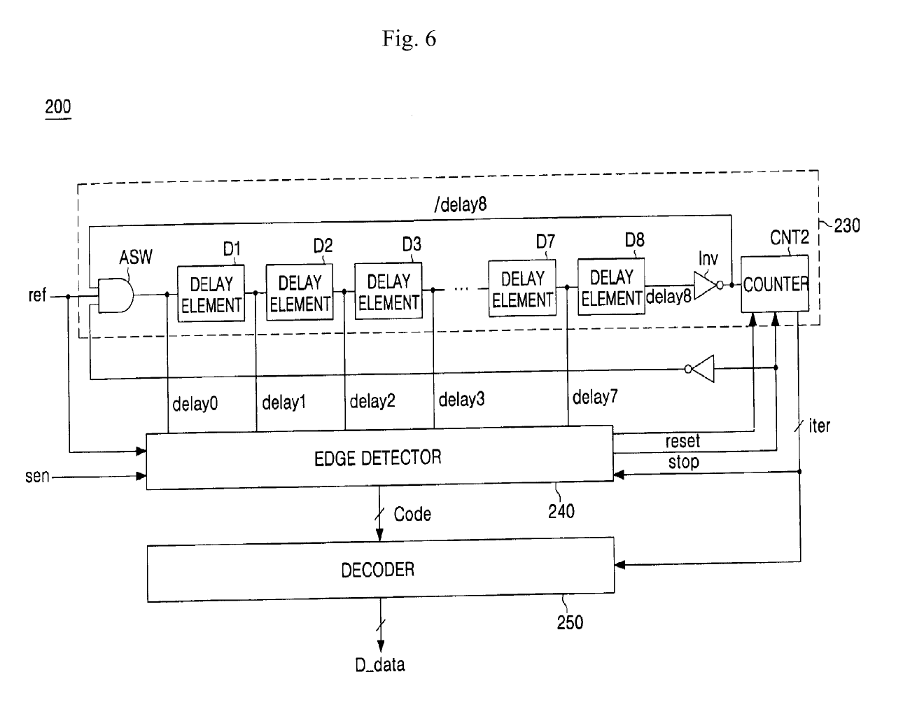

FIG. 6 is a circuit diagram of a delay time measurement circuit including a delay chain having a feedback structure according to another exemplary embodiment of the present invention.

The delay measurement circuit 200 shown in FIG. 6 comprises a delay chain 230, an edge detector 240 and a decoder 250. The delay chain 230 has a plurality of delay elements D1 to D8, a switch ASW, an inverter Inv and a counter CNT2, similar to FIG. 4. The delay elements D1 to D8 are connected in series, and a delay signal delay8 output from the last delay element D8 among the delay elements D1 to D8 connected in series is inverted by the inverter Inv and applied to the switch ASW. In other words, the delay chain 230 of FIG. 6 also has a feedback structure as shown in FIG. 4. The switch ASW is implemented by a 3-input AND gate, and outputs a delay signal delay0 in response to a reference signal ref, an inverted delay signal /delay8 and a count stop signal stop output from the edge detector 240. The switch ASW is implemented by an AND gate in FIG. 6, but may be implemented by the switch SW as shown in FIG. 4. In response to the delay signal delay8 output from the last delay element D8 among the delay elements D1 to D8, the counter CNT2 counts the number of operations of delaying the reference signal ref in the delay chain 230 and outputs an iterative count signal iter. The counter CNT2 is reset in response to a counter reset signal reset.

The edge detector 240 receives the reference signal, a measurement signal sen and the delay signals delay0 to delay7, outputs the counter reset signal reset and the count stop signal stop to the counter CNT2 in response to rising or falling edges of the respective received signals, and outputs a code signal Code to the decoder 250.

When detecting an edge of the reference signal, the edge detector 240 outputs the counter reset signal reset. The edge detector 240 detects and counts edges of the delay signals delay0 to delay7, and is reset in response to the iterative count signal iter applied from the counter CNT2. When detecting an edge of the measurement signal sen, the edge detector 240 outputs the count stop signal stop and the code signal Code corresponding to the counted delay signals delay0 to delay7.

The decoder 250 decodes the code signal Code applied from the edge detector 240 and the iterative count signal iter applied from the counter CNT2, thereby outputting a measured delay value D_data. As described with reference to FIG. 4, the measured delay value D_data may be output in the form set by a user.

In FIG. 4, the code generation unit 140 senses states of the delay signals delay0 to delay7 to output the code signals C0 to C7, and thus it must be considered whether the number of feedbacks is an odd number or an even number. However, the delay time measurement circuit 200 of FIG. 6 detects edges of the reference signal ref, the measurement signal sen and the delay signals delay0 to delay7 to calculate the measured delay value D_data, and thus it is unnecessary to consider the number of feedbacks of the delay chain 230. Consequently, the XOR gates XOR0 to XOR7 included in the code generation unit 140 of FIG. 4 are not required in the delay time measurement circuit 200 of FIG. 6.

When the counter CNT2 is configured to be reset in response to the count stop signal stop, the edge detector 240 does not need to output the counter reset signal reset to the counter CNT2.

Thus far, the present invention has been described with reference to a case in which the reference signal ref and the measurement signal sen are switched from low level to high level, but also can be applied to a case in which the signals are switched from high level to low level. In addition, logical gates such as the AND gate ASW, the XOR gates XOR0 to XOR7 and the OR gate OR8 shown in FIG. 4 or 6 can be replaced with other logical gates according to the set levels of respective signals. Also, the number of delay elements included in the delay chains 130 and 230 can be changed.

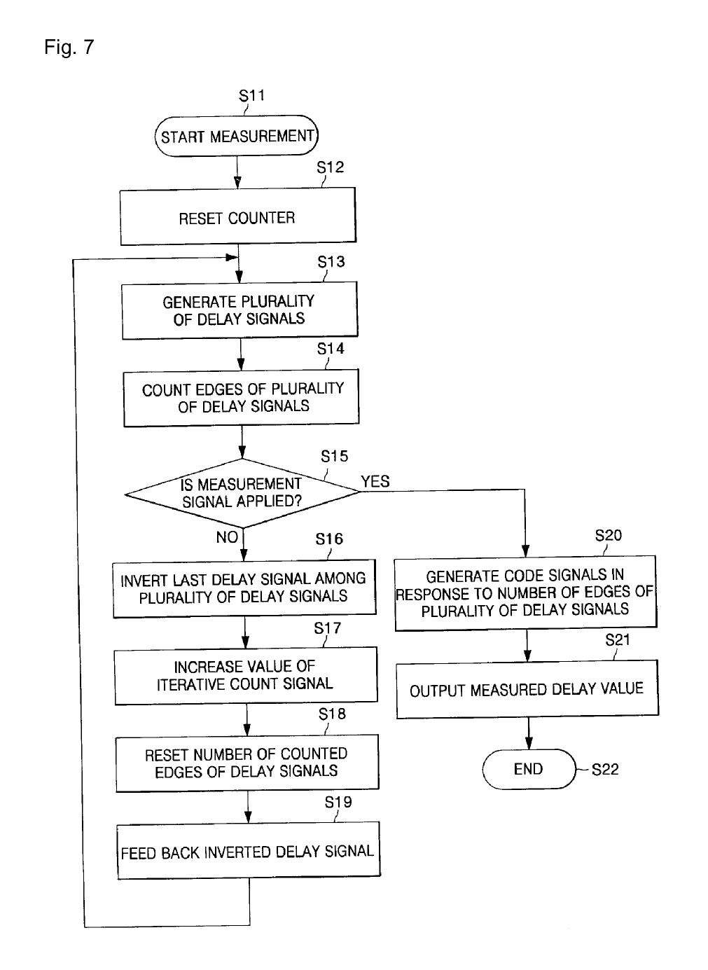

FIG. 7 is a flowchart showing a delay time measurement method of the delay time measurement circuit 200 of FIG. 6. The delay time measurement method of FIG. 7 will be described with reference to FIG. 6. First, when a reference signal ref is applied to the switch ASW of the delay chain 230, it is started to measure a delay time (step 11). Here, when detecting an edge of the reference signal ref, the edge detector 240 outputs a counter reset signal reset, thereby resetting the counter CNT2 (step 12). The delay elements D1 to D8 of the delay chain 230 connected in series delay a delay signal delay0 applied from the switch ASW in sequence, thereby generating a plurality of delay signals delay1 to delay8 (step 13). The edge detector 240 counts edges of the delay signals delay0 to delay7 (step 14).

While the delay signals delay0 to delay8 are being applied, the edge detector 240 determines whether or not the measurement signal sen is applied (step 15). When the measurement signal sen is not applied, the edge detector 240 does not output a count stop signal stop. The delay chain 230 inverts the last delay signal delay8 among the delay signals delay0 to delay8 (step 16) and transfers the last delay signal delay8 to the counter CNT2. The counter CNT2 increases the value of an iterative count signal iter by 1 in response to the inverted delay signal /delay8 (step 17). The edge detector 240 resets the number of the counted edges of the delay signals delay0 to delay7 in response to the iterative count signal iter (step 18). Then, the delay chain 230 feeds back the inverted delay signal /delay8 (step 19), and generates a plurality of delay signals delay0 to delay8 again (step 13).

When the measurement signal sen is applied while the delay signals delay0 to delay7 are being applied, the edge detector 240 outputs a code signal Code corresponding to the number of edges of the delay signals delay0 to delay7 counted until the measurement signal sen is applied (step 20). In addition, the edge detector 240 outputs the count stop signal stop to the counter CNT2 in response to the measurement signal sen. And, the decoder 250 decodes the iterative count signal iter applied from the counter CNT2 and the code signal Code, thereby outputting a measured dealy value D_data (step 21).

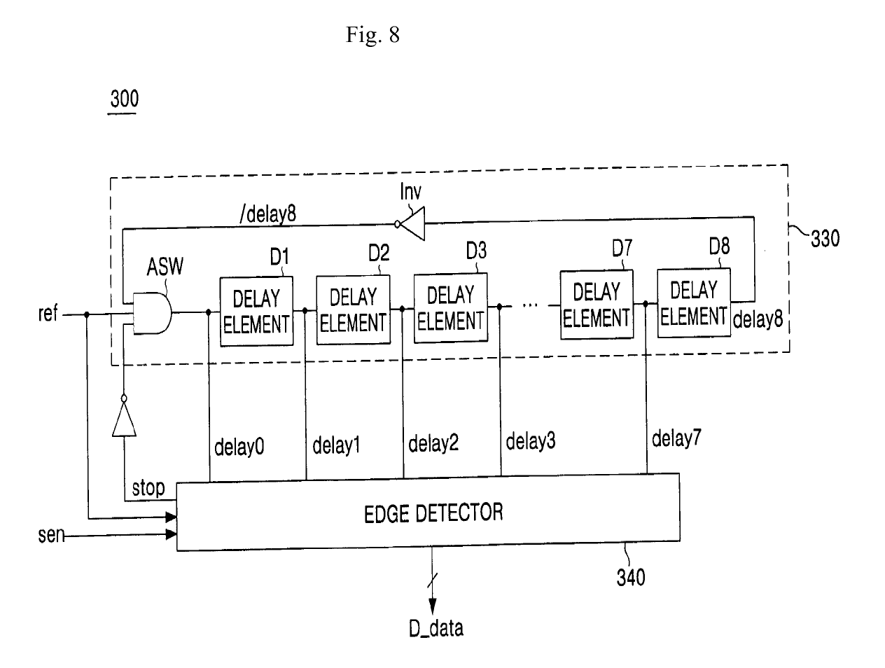

FIG. 8 is a circuit diagram of a delay time measurement circuit including a delay chain having a feedback structure according to still another exemplary embodiment of the present invention. Unlike the delay chains 130 and 230 of FIGS. 4 and 6, a delay chain 330 of FIG. 8 does not have a counter.

In response to a rising or falling edge of a reference signal ref, an edge counter 340 detects an edge of a plurality of delay signals delay0 to delay7 and begins to count edges of the delay signals delay0 to delay7. And, when an edge of a measurement signal sen is detected, the edge counter 340 outputs the number of the counted edges of the delay signals delay0 to delay7 as a measured delay value D_data.

The delay time measurement circuit 300 of FIG. 8 detects edges of the delay signals delay0 to delay7 as the delay time measurement circuit 200 of FIG. 6 and thus can operate regardless of whether the number of feedbacks is an odd number or an even number. However, unlike in the delay time measurement circuit 200 of FIG. 6, the edge counter 340 can output the measured delay value D_data in the delay time measurement circuit 300 of FIG. 8. Thus, the delay time measurement circuit 300 does not require either of a counter or a decoder.

The delay time measurement circuit and method according to exemplary embodiments of the present invention can be used in a variety of electronic devices, and in particular, used in the cited invention as various sensors or Analog-to-Digital Converters (ADCs).

While the invention has been shown and described with reference to certain exemplary embodiments thereof, it will be understood by those skilled in the art that various changes in form and details may be made therein without departing from the spirit and scope of the invention as defined by the appended claims.

1. A delay time measurement circuit, comprising:
a delay chain unit selecting either a reference signal indicating a start of delay time measurement or a feedback signal to receive the selected signal as an input signal, having a plurality of delay elements connected in series to delay the input signal, inverting the delayed input signal, outputting the inverted signal as the feedback signal, and counting a number of feedback iterations of the inverted signal to output an iterative count signal;
a code generation unit for comparing a measurement signal with the input signal and each of a plurality of delay signals applied from the delay elements except a last delay element to measure a delay time of the measurement signal with respect to the reference signal to generate code signals; and
a decoder for decoding the code signals and the iterative count signal to output a measured delay value.

2. The delay time measurement circuit of claim 1, wherein the delay chain unit comprises:
a switch for selecting the reference signal or the feedback signal and outputting the selected signal as the input signal;
a delay chain having the delay elements connected in series and receiving and delaying the input signal to output the delay signals;
an inverter for inverting a delay signal output from the last delay element of the delay chain to output the feedback signal; and
a counter for outputting the iterative count signal in response to the feedback signal.

3. The delay time measurement circuit of claim 2, wherein the switch selects either the reference signal or the feedback signal in response to the iterative count signal and outputs the input signal.

4. The delay time measurement circuit of claim 2, wherein the code generation unit comprises:
a comparative delay signal generator for generating the input signal and the delay signals as a plurality of comparative delay signals when the iterative count signal is an even number, and inverting the input signal and the delay signals to output the inverted signals as the comparative delay signals when the iterative count signal is an odd number;
a plurality of comparators for comparing the respective comparative delay signals with the measurement signal to generate the code signals; and
a first logical gate for outputting a counter reset signal for controlling the counter in response to the code signals.

5. The delay time measurement circuit of claim 4, wherein the counter is reset in response to the counter reset signal.

6. The delay time measurement circuit of claim 4, wherein the comparative delay signal generator comprises:
a plurality of XOR gates for performing an XOR operation on one lowermost bit of the iterative count signal and each of the input signal and the comparative delay signals.

7. The delay time measurement circuit of claim 4, wherein the comparators are a plurality of first AND gates for performing an AND operation on the respective comparative delay signals and the measurement signal.

8. The delay time measurement circuit of claim 4, wherein the comparators are D flip-flops latching and outputting the measurement signal in response to the comparative delay signals and reset in response to the switch setting signal.

9. The delay time measurement circuit of claim 4, wherein the first logical gate is an OR gate for performing an OR operation on the code signals.

10. The delay time measurement circuit of claim 4, wherein the decoder multiplies a number of the delay elements by the iterative count signal and adds a value corresponding to the code signals to the multiplied result to output the measured delay value.

11. The delay time measurement circuit of claim 2, wherein the code generation unit comprises:
an edge detector outputting a reset signal for resetting the counter in response to an edge of the reference signal, outputting a count stop signal to the counter in response to an edge of the measurement signal, outputting the code signals corresponding to a number of edges of the delay signals, and reset in response to the iterative count signal.

12. The delay time measurement circuit of claim 11, wherein the counter outputs the iterative count signal to the decoder in response to the count stop signal and is reset in response to the reset signal.

13. The delay time measurement circuit of claim 11, wherein in response to the count stop signal, the counter outputs the iterative count signal to the decoder and is reset.

14. The delay time measurement circuit of claim 11, wherein the decoder multiplies a number of the delay elements by the iterative count signal and adds a value obtained by decoding the code signals to the multiplied result to output the measured delay value.

15. The delay time measurement circuit of claim 11, wherein the switch is a second AND gate for performing an AND operation on the reference signal, the feedback signal and the count stop signal to output the input signal.

16. A delay time measurement circuit, comprising:
a delay chain unit selecting either a reference signal indicating a start of delay time measurement or a feedback signal to receive the selected signal as an input signal, having a plurality of delay elements connected in series to delay the input signal, inverting the delayed input signal, and outputting the inverted signal as the feedback signal; and
an edge counter for counting edges of the input signal and delay signals applied from the delay elements in response to an edge of the reference signal, and outputting a measured delay value corresponding to a number of the counted edges of the input signal and the delay signals in response to an edge of a measurement signal.

17. The delay time measurement circuit of claim 16, wherein the delay chain unit comprises:
a switch for selecting the reference signal or the feedback signal to output the selected signal as the input signal;
a delay chain having the delay elements connected in series and receiving and delaying the input signal to output the delay signals; and
an inverter for inverting a delay signal output from a last delay element of the delay chain to output the feedback signal.

18. A delay time measurement method, comprising:
generating a plurality of delay signals in response to either a reference signal or a feedback signal, and determining whether or not a measurement signal is ascertained;
when the measurement signal is not ascertained, inverting a last delay signal among the delay signals to output the feedback signal, and feeding back the feedback signal to the step of generating the delay signals; and
when the measurement signal is ascertained, counting edges of delay signals generated until the measurement signal is applied, and generating a measured delay value using a number of the counted edges of the delay signals and a number of operations of outputting the feedback signal.

19. The delay time measurement method of claim 18, wherein generating the delay signals and determining whether or not the measurement signal is applied comprises:
when the reference signal is applied, resetting a number of operations of generating the feedback signal;
delaying the reference signal or the feedback signal for different times to output the delay signals;
counting edges of the delay signals; and
determining whether or not the measurement signal is ascertained.

20. The delay time measurement method of claim 19, wherein feeding back the feedback signal comprises:
when the measurement signal is not ascertained, inverting the last delay signal among the delay signals to generate the feedback signal;
in response to the feedback signal, increasing a value of an iterative count signal and outputting the iterative count signal;
resetting the number of the counted edges of the delay signals in response to the iterative count signal; and
feeding back the feedback signal to the step of generating the delay signals.

21. The delay time measurement method of claim 20, wherein generating the measured delay value comprises:
when the measurement signal is ascertained, generating code signals in response to the number of the edges of the delay signals generated until the measurement signal is ascertained; and
decoding the iterative count signal and the code signals to output the measured delay value.
